(19) United States
(12) Patent Application Publication
(10) Pub. No.: US 2015/0047564 A1
(43) Pub. Date: Feb. 19, 2015

(54) CHEMICAL VAPOR DEPOSITION DEVICE

(71) Applicant: Samsung SDI Co., Ltd., Yongin-si (KR)

(72) Inventor: Woo-Jin Kim, Yongin-si (KR)

(73) Assignee: Samsung SDI Co., Ltd., Yongin-si (KR)

(21) Appl. No.: 13/968,328

(22) Filed: Aug. 15, 2013

(51) Int. Cl. C23C 16/04

(52) U.S. Cl. CPC C23C 16/042
USPC 118/721; 118/720

(57) ABSTRACT

A chemical vapor deposition device includes a support member configured to support a lower surface of a substrate; a shadow frame configured to cover an edge portion of an upper surface of the substrate; and a jacket having a purge gas supply opening configured to supply a purge gas such that the purge gas exits the purge gas supply opening from a location below the lower surface of the substrate. The jacket is adjacent to a portion of the shadow frame and configured to cover a portion of the lower surface of the substrate. An exhaust unit is located at the jacket or is between the jacket and the shadow frame.

### BACKGROUND

1. Field

An aspect of the present invention relates to a chemical vapor deposition device.

2. Description of the Related Art

Generally, a chemical vapor deposition device may be used in depositing various substrates. For example, the chemical vapor deposition device may be used in depositing a substrate that is necessary when manufacturing a solar cell or in depositing a substrate that is necessary when manufacturing a display panel. Such a chemical vapor deposition device may deposit a substrate by spraying deposition gas on the upper side. Here, a purge gas may be sprayed from the lower side of the substrate to prevent deposition of the deposition gas on the lower surface of the substrate or non-uniform deposition of the deposition gas on the side surface of the substrate.

The supplied purge gas may move from the lower surface of the substrate to the upper surface of the substrate. Furthermore, the substrate may not be appropriately deposited due to movement of the structure that fixes or supports the substrate at the edge area of the substrate. As a result, the purge gas is often not smoothly exhausted or is not uniformly deposited at the substrate edge area.

### SUMMARY

This summary is provided to introduce a selection of concepts that are further described in the detailed description. This summary is not intended to identify key or essential features of the claimed subject matter, nor is it intended to be used as an aid in limiting the scope of the claimed subject matter.

Aspects of embodiments of the present invention are directed toward a chemical vapor deposition device capable of improving film uniformity at an edge portion and/or a lower surface of a substrate.

According to aspects of embodiments of the present invention, deposition uniformity may be improved by preventing purge gas from moving to the upper surface of the substrate or from being stored in the edge area of the substrate. Furthermore, according to aspects of embodiments of the present invention, a smooth exhaust of the purge gas may be promoted by discharging the purge gas to the side of the jacket.

In one embodiment, a chemical vapor deposition device includes a support member configured to support a lower surface of a substrate; a shadow frame configured to cover an edge portion of an upper surface of the substrate; and a jacket having a purge gas supply opening configured to supply a purge gas such that the purge gas exits the purge gas supply opening from a location below the lower surface of the substrate. The jacket may be adjacent to a portion of the shadow frame and configured to cover a portion of the lower surface of the substrate, and an exhaust unit may be located at the jacket or between the jacket and the shadow frame.

In one embodiment, the exhaust unit of the chemical vapor deposition device is configured to discharge at least a portion of the purge gas in a direction parallel to the lower surface of the substrate.

In one embodiment, the chemical vapor deposition device also includes a chamber housing the support member, the shadow frame, and the jacket. In some embodiments, the chemical vapor deposition device includes a suction unit at a side or bottom of the chamber. In some embodiments, the suction unit is at a bottom of the chamber.

In another embodiment, the purge gas supply opening of the chemical vapor deposition device extends through the jacket.

In one embodiment, the jacket of the chemical vapor deposition device includes a purge gas supply unit coupled with the purge gas supply opening and a jacket body coupled to the purge gas supply unit. The purge gas supply unit may have a first thickness, and the jacket body may have a second thickness that is different from the first thickness. In some embodiments, the first thickness is less than the second thickness. In another embodiment, a space is between the shadow frame and the purge gas supply unit, such that the space is coupled to the exhaust unit.

In another embodiment, the purge gas supply opening of the chemical vapor deposition device is configured to supply a purge gas to the lower surface of the substrate, and the exhaust unit is configured to discharge at least a portion of the purge gas supplied from the purge gas supply opening to an outside of the jacket. In another embodiment, the exhaust unit is configured to prevent the purge gas from being supplied toward the upper surface of the substrate by discharging an excess portion of the purge gas to the outside of the jacket. In another embodiment, the chemical vapor deposition device further includes a shower head configured to spray a deposition gas toward the upper surface of the substrate. In another embodiment, the exhaust unit is configured to discharge a portion of the purge gas supplied from the purge gas supply opening and a portion of the deposition gas supplied from the shower head to the outside of the jacket.

In one embodiment, the exhaust unit of the chemical vapor deposition device is between the shadow frame and the jacket. In another embodiment, the shadow frame further includes a fixing unit and a contact unit. The fixing unit may be adjacent to and in contact with the edge portion of the upper surface of the substrate, and the contact unit may be adjacent to the exhaust unit. The shadow frame may be configured to fix the substrate between the shadow frame and the support member.

In another embodiment, the exhaust unit of the chemical vapor deposition device includes a plurality of exhaust units, and the jacket further includes a support unit between two neighboring ones of the plurality of exhaust units in the first direction. A portion of the jacket may be in contact with a portion of the shadow frame at each support unit. In some embodiments, the exhaust unit has a depth that is about 20% to about 75% of a thickness of the jacket. In another embodiment, the exhaust unit has a diameter that is about 20% to about 75% of the thickness of the jacket.

In one embodiment, the exhaust unit of the chemical vapor deposition device has a first width in a first direction parallel to the substrate that is different from a second width of the support unit in the first direction. In some embodiments, a ratio of the first width to the second width is between 0.25 and 4. In another embodiment, the exhaust unit has a diameter in a first direction parallel to the substrate that is different from a shortest distance between two neighboring ones of the plurality of exhaust units. In some embodiments, the diameter of the exhaust unit to the shortest distance between two neighboring ones of the plurality of exhaust units is between 0.25 and 4.

In another embodiment, a chemical vapor deposition device includes a chamber housing a support member configured to support a lower surface of a substrate; a shadow frame configured to cover an edge portion of an upper surface of the substrate; and a jacket having a purge gas supply opening configured to supply a purge gas such that the purge gas exits the purge gas supply opening from a location below the lower surface of the substrate. The jacket may be adjacent to a portion of the shadow frame and configured to cover a portion of the lower surface of the substrate. An exhaust unit may be located at the jacket or between the jacket and the shadow frame. A suction unit may be coupled to the chamber and configured to suction a gas from the chamber.

In one embodiment, the suction unit of the chemical vapor deposition device includes a suction pipe coupled to the chamber and a vacuum pump coupled to the suction pipe. In some embodiments, a portion of the purge gas is discharged through the exhaust unit to an outside of the chamber through the suction unit.

In another embodiment, a portion of the purge gas and a portion of the deposition gas of the chemical vapor deposition device is discharged through the exhaust unit to an outside of the chamber through the suction unit.

### BRIEF DESCRIPTION OF THE DRAWINGS

FIG. 1 is an elevation view of a chemical vapor deposition device according to one embodiment of the present invention.

FIG. 2 is an enlarged elevation view of portion A of the chemical vapor deposition device of FIG. 1.

FIG. 3 is a side elevation view illustrating a side surface of a jacket and a shadow frame of the portion of the chemical vapor deposition device of FIG. 2.

FIG. 4 is an elevation view of a chemical vapor deposition device according to another embodiment of the present invention.

FIG. 5 is an enlarged elevation view of portion B of the chemical vapor deposition device of FIG. 4.

FIG. 6 is a side elevation view illustrating a side surface of a jacket and a shadow frame of the portion of the chemical vapor deposition device of FIG. 5.

FIG. 7 is an elevation view of a chemical vapor deposition device according to another embodiment of the present invention.

FIG. 8 is an enlarged elevation view of portion C of the chemical vapor deposition device of FIG. 7.

### DETAILED DESCRIPTION

The present invention will now be described more fully with reference to the accompanying drawings, in which embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art. Like reference numerals in the drawings denote like elements, and thus their descriptions will be omitted. Terms such as “including,” “having,” or “comprising,” may be intended to indicate a plurality of components unless the terms are used with the term “only.” Terms such as “first” and “second” may be used to describe various components, but the invention is not limited by such terms. The terms are used only to distinguish one component from another.

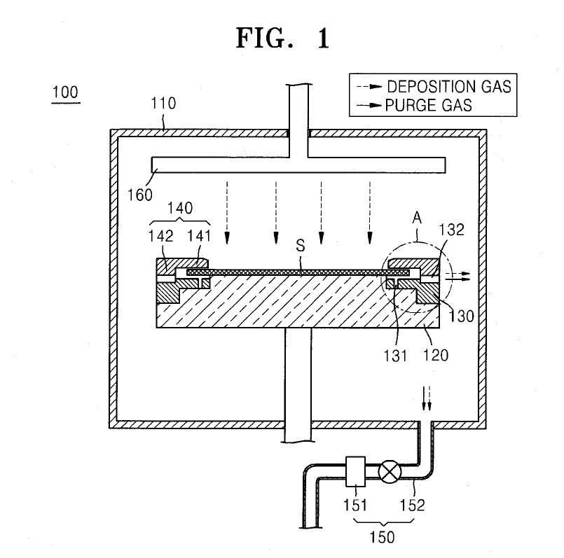

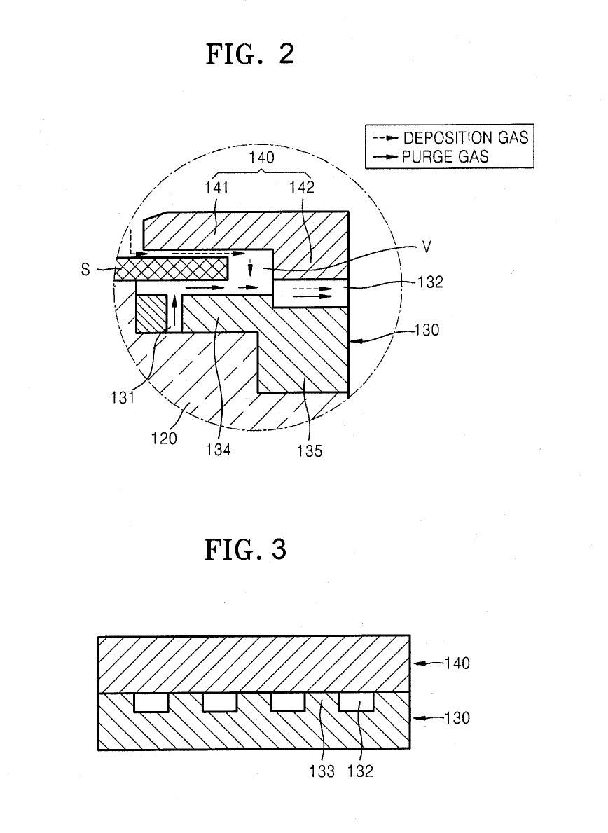

FIG. 1 is an elevation view of a chemical vapor deposition device 100 according to an embodiment of the present invention. FIG. 2 is an enlarged elevation view of portion A of the chemical vapor deposition device of FIG. 1. FIG. 3 is a side elevation view illustrating a side surface of a jacket 130 and a shadow frame 140 of the portion of the chemical vapor deposition device 100 of FIG. 2.

Referring to FIGS. 1 to 3, in some embodiments, the chemical vapor deposition device 100 includes a chamber 110 in which a space is formed. Further, in some embodiments, the chemical vapor deposition device 100 includes a support member 120 for placing the substrate S. In some embodiments, a heater is installed to apply heat to the placed substrate S.

Furthermore, in some embodiments, the chemical vapor deposition device 100 covers the external part of the support member 120, and includes a jacket 130 having a purge gas supply opening 131 for supplying purge gas to the substrate S. In some embodiments, a purge gas supply opening 131 is formed where a part of the external side of the jacket 130 is placed away from a part of the external side of the support member 120 by a certain distance. Furthermore, the purge gas supply opening 131 may be formed to penetrate through the jacket 130 from a bottom surface of the jacket. In the embodiment described in further detail below, the purge gas supply opening 131 is formed through the jacket 130 for the convenience of explanation.

The above purge gas supply opening 131 may be connected to a purge gas supply line. In one embodiment, the purge gas supply line is bent along the internal side of the support member 120, and is connected to the outside through a part of the support member 120.

Furthermore, the jacket 130 may include a purge gas supply unit 134 where the purge gas supply opening 131 is formed, and a jacket body unit or jacket body 135 connected to the purge gas supply unit 134, where at least a part of the jacket body unit or jacket body 135 supports the shadow frame 140.

The above jacket 130 may be formed in a multi-stepped manner. In detail, a thickness of the purge gas supply unit 134 may be set to be different from a thickness of the jacket body unit or jacket body 135. In particular, the thickness of the purge gas supply unit 134 may be formed smaller than the thickness of the jacket body unit or jacket body 135.

Furthermore, the jacket 130 may include an exhaust unit 132 that exhausts part of the purge gas, which is supplied from the purge gas supply opening 131 to the substrate S, to the outside. In these embodiments, the exhaust unit 132 is formed in various positions with respect to the jacket 130, exhausting part of the purge gas in a direction toward the external side of the jacket 130 from the support member 120, as described above.

Furthermore, the exhaust unit 132 may be formed at various positions. For example, the exhaust unit 132 may be formed at the external side of the jacket 130. In particular, the exhaust unit 132 may be formed at the external side of the jacket body unit or jacket body 135 where the shadow frame 140 contacts the jacket 130. In some embodiments, the exhaust unit 132 is formed as a hole penetrating through the jacket 130. In the embodiments described hereinafter, the description will center on the embodiment in which the purge gas supply opening 131 is formed where a part of the external side of the jacket 130 is placed away from a part of the external side of the support member 120 by a certain distance.

The gas exhausted through the exhaust unit 132 may be inserted in a downward direction from the external side of the jacket body unit or jacket body 135 that contacts the shadow frame 140. Further, the exhaust unit 132 may extend in a longitudinal direction along the jacket 130.

In one embodiment, the exhaust unit 132 is formed to be connected to a space V formed by the upper side of the purge gas supply unit 134, the border of the substrate S, and the lower side of the shadow frame 140.

In another embodiment, a plurality of exhaust units 132 are provided. In these embodiments, the plurality of exhaust units 132 are formed at regular intervals. In particular, as described above, if there are a plurality of exhaust units 132, the jacket 130 may be adjacent to the exhaust unit 132 so as to include a support unit 133 that supports a part of the shadow frame 140.

A plurality of exhaust units 132 may be placed in various forms with a plurality of purge gas supply openings 131. For example, each exhaust unit 132 and each purge gas supply opening 131 may be placed on one straight line. In this embodiment, each exhaust unit 132 is formed only on the jacket body unit or jacket body 135 so that each exhaust unit 132 is not connected to the purge gas supply opening 131. Further, each exhaust unit 132 may be formed on the external side of the purge gas supply unit 134 and the jacket body unit or jacket body 135 so as to be connected to each purge gas supply opening 131. Further, each exhaust unit 132 and each purge gas supply opening 131 may be alternately formed. In some embodiments, each exhaust unit 132 is formed on only the jacket body unit or jacket body 135. The description below will center on the embodiment where each exhaust unit 132 and each purge gas supply opening 131 is alternately formed for the convenience of explanation.

The exhaust unit 132 and the support unit 133 may be formed to have different heights. For example, the height of the exhaust unit 132 may be shorter than the height of the support unit 133. In particular, the exhaust unit 132 may be inserted from the external surface of the jacket body unit or jacket body 135, and the support unit 133 may be projected from the external surface of the jacket body unit or jacket body 135, or the support unit 133 may be formed in the same manner as that of the external surface of the jacket body unit or jacket body 135. That is, the exhaust unit 132 and the support unit 133 may be alternately formed or be formed with a certain ratio so as to form an uneven structure.

In one embodiment, the ratio of the exhaust unit 132 to the support unit 133 is 4:1 or 1:4. For example, if the width of the exhaust unit 132 is 4, the width of the support unit 133 is 1, and if the width of the exhaust unit 132 is 1, the width of the support unit 133 is 4.

In particular, in embodiments when the width of the exhaust unit 132 exceeds four times the width of the support unit 133, the support unit 133 may be deformed so that the support unit 133 fails to support the shadow frame 140, or the position of the shadow frame 140 deviates.

In contrast, in embodiments where the width of the exhaust unit 132 is less than ¼ the width of the support unit 133, the size of the exhaust unit 132 may be too small to smoothly exhaust the deposition gas or purge gas.

In another embodiment where the ratio of the exhaust unit 132 to the support unit 133 is 4:1 or 1:4, the ratio includes the diameter of the exhaust unit 132 in a first direction parallel to the substrate S, and the shortest distance between two adjacent exhaust units 132 where there are a plurality of exhaust units 132. For example, if the diameter of each exhaust unit 132 is 4, the shortest distance between two adjacent exhaust units 132 of the plurality of exhaust units 132 may be 1, and if the diameter of each exhaust unit 132 is 1, the shortest distance between two adjacent exhaust units 132 of the plurality of exhaust units 132 may be 4. In particular, in embodiments when the diameter of each exhaust unit 132 exceeds four times the shortest distance between two adjacent exhaust units 132 of the plurality of exhaust units 132, the support unit 133, which is located between adjacent exhaust units 132 of the plurality of exhaust units 132, may be deformed so that the support unit 133 fails to support the shadow frame 140, or the position of the shadow frame 140 deviates. In contrast, in embodiments where the diameter of each exhaust unit 132 is less than ¼ the shortest distance between two adjacent exhaust units 132 of the plurality of exhaust units 132, the size of the exhaust unit 132 may be too small to smoothly exhaust the deposition gas or purge gas.

In some embodiments, the depth or diameter of the exhaust unit 132 is between about 20% and about 75% the thickness of the jacket 130. In these embodiments, if the depth or diameter of the exhaust unit 132 is less than 20% of the thickness of the jacket 130, the purge gas and deposition gas may be not smoothly discharged, and the deposition uniformity of the substrate S is not secured. Further, if the depth or diameter of the exhaust unit 132 exceeds 75% of the thickness of the jacket 130, the jacket 130 may not effectively support the shadow frame 140 such that the position of the shadow frame 140 may deviate or the substrate S may break.

In some embodiments, the chemical vapor deposition device 100 contacts the jacket 130, and includes a shadow frame 140, at least part of which is placed on the upper surface of the substrate S. In this embodiment, the shadow frame 140 includes a fixing unit 141 placed on the upper surface of the substrate S. Further, the shadow frame 140 may include a contact unit 142 which is bent from the fixing unit 141. In this embodiment, the contact unit 142 is placed starting at the border of the substrate S at regular intervals, and contacts one surface of the jacket 130. In particular, the exhaust unit 132 may be connected to a space V formed by the upper side of the purge gas supply unit 134, the border of the substrate S, and the lower side of the shadow frame 140, and may exhaust the purge gas to the outside.

The chemical vapor deposition device 100 may be installed inside the chamber 110, and may include a shower head 160 that sprays the deposition gas onto or toward the substrate S. In this embodiment, the shower head 160 supplies deposition gas from the outside and sprays the deposition gas onto or toward the substrate S.

Further, the chemical vapor deposition device 100 may allow for the insertion of the substrate into the inside of the chamber 110, where the substrate S may be safely placed on the support member 120. In this embodiment, the shadow frame 140 is spaced apart from the substrate S at regular intervals.

In embodiments where the substrate S is placed as described above, the support member 120 is raised up so that the substrate S may be in contact with the shadow frame 140. Specifically, the substrate S may be fixed by placing the fixing unit 141 on the upper surface of the substrate S to contact the substrate S.

In these embodiments, the purge gas is supplied to the substrate S through the shower head 160, and the purge gas is supplied from the lower surface of the substrate S through the purge gas supply opening 131. In particular, the purge gas may be externally supplied to the purge gas supply opening 131 through a purge gas supply line. In one embodiment, diethylzinc (DEZ) and water vapor (H2O) are used as the deposition gas, and Argon (Ar) is used as the purge gas. However, the deposition gas and the purge gas of the embodiments of the present invention are merely examples, and any appropriate deposition gas and/or purge gas used in chemical vapor deposition methods may be included.

In some embodiments where the deposition gas and the purge gas are respectively supplied, the purge gas prevents the deposition gas from flowing into the lower surface of the substrate S. Specifically, the deposition gas may flow from the central part of the substrate S to the border part, and may enter into a space between the substrate S and the fixing unit 141. In particular, the deposition gas may flow into the space V formed by the upper side of the purge gas supply unit 134, the border of the substrate S, and the lower side of the shadow frame 140. Further, in some embodiments, the purge gas flows to the space between the lower surface of the substrate S and the upper surface of the jacket 130 through the purge gas supply opening 131. In some embodiments, the purge gas flows into the space V formed by the upper side of the purge gas supply unit 134, the border of the substrate S, and the lower side of the shadow frame 140.

In some embodiments, the deposition gas and the purge gas are balanced according to the mutual pressure between the two gases, and the deposition gas maintains this mutual pressure state in the space V formed by the upper side of the purge gas supply unit 134, the border of the substrate S, and the lower side of the shadow frame 140. In this embodiment, a non-uniform deposition may be performed as the concentration of the deposition gas is increased on the border of the substrate S by the deposition gas stored in the space V formed by the upper side of the purge gas supply unit 134, the border of the substrate S, and the lower side of the shadow frame 140.

Further, if the pressure of the deposition gas is smaller than the pressure of the purge gas, the purge gas may be discharged to the inside of the chamber 110 through the space between the shadow frame 140 and the substrate S from space V, formed by the upper side of the purge gas supply unit 134, the border of the substrate S, and the lower side of the shadow frame 140. In this embodiment, as explained above, the deposition of the border area of the substrate S may become uneven where the deposition of the border portion of the substrate S is prevented. In particular, the shadow frame 140 may be moved by the pressure of the purge gas.

However, in the case of the chemical vapor deposition device 100 according to embodiments of the present invention, by discharging the purge gas to the outside through the exhaust unit 132, the uneven deposition of the border portion of the substrate S is prevented.

Specifically, in some embodiments, a part of the purge gas supplied through the purge gas supply opening 131 is discharged to a side of the chamber 110 through the exhaust unit 132. For example, as described above, the exhaust unit 132 may discharge the purge gas to the outside of the jacket 130 by connecting the space V formed by the upper side of the purge gas supply unit 134, the border of the substrate S, and the lower side of the shadow frame 140, with the border of the substrate S, to discharge the purge gas to the outside of the jacket 130.

Likewise, in one embodiment, the gas exhausted or discharged through the exhaust unit 132 is connected to at least one of space V formed by the upper side of the purge gas supply unit 134, the border of the substrate S and the lower side of the shadow frame 140, or the purge gas supply opening 131, and may guide the purge gas to the outside of the jacket 130. Further, the exhaust unit 132 may discharge a portion of the deposition gas to the outside of the jacket 130.

Moreover, in some embodiments, when discharged, the purge gas does not flow into the space V between the substrate S and the fixing unit 141; and, thus, the deposition gas does not need to flow to the lower surface of the substrate S. Further, the deposition gas uniformity at the border area of the substrate S may be maintained at a constant.

In particular, comparative examples of the embodiment where the exhaust unit 132 is not provided, and the embodiment where the exhaust unit 132 is provided, are shown in the comparative example and the experimental example below. In these examples, T denotes the thickness of the deposited film, and the unit is the micrometer (μm). Rs denotes the resistance of the deposited film, and the unit is the Ω/sq. Further, the horizontal and vertical numbers denote the x-coordinate and y-coordinate of the substrate S, respectively. Additionally, the percentage value indicates the relation between the maximum value and the minimum value (%) among the data, and may be acquired using the following formula: (maximum value−minimum value)/(maximum value+minimum value) multiplied by 100.

Comparative Example

| | 8.2% | | | | |
|---|---|---|---|---|---|
| T (μm) | 15 | 125 | 235 | 345 | 455 |
| 355 | 1.1736 | 1.1378 | 1.0665 | 1.0914 | 1.1104 |
| 270 | 1.1831 | 1.1378 | 1.1356 | 1.0996 | 1.1481 |
| 185 | 1.1514 | 1.2469 | 1.2561 | 1.2346 | 1.1384 |
| 100 | 1.1518 | 1.1253 | 1.1112 | 1.1822 | 1.1393 |
| 15 | 1.1401 | 1.1957 | 1.0996 | 1.1321 | 1.1377 |
| | 20.7% | | | | |
| Rs (Ω/sq) | 15 | 125 | 235 | 345 | 455 |
| 355 | 13.65 | 16.6 | 17.4 | 16.8 | 14.9 |
| 270 | 12.606 | 13.12 | 14.54 | 14.33 | 13.32 |
| 185 | 13.33 | 13.54 | 16.17 | 15.65 | 13.68 |
| 100 | 12.7 | 14.92 | 17.21 | 16.65 | 13.62 |
| 15 | 13.24 | 15.26 | 19.2 | 17.39 | 15.25 |

Experimental Example

| | 3.7% | | | | |
|---|---|---|---|---|---|
| T (μm) | 15 | 125 | 235 | 345 | 455 |
| 355 | 1.179 | 1.2307 | 1.16 | 1.1833 | 1.1843 |
| 270 | 1.1548 | 1.2296 | 1.1602 | 1.1918 | 1.1952 |
| 185 | 1.1847 | 1.2165 | 1.1427 | 1.171 | 1.1647 |
| 100 | 1.1873 | 1.1894 | 1.1481 | 1.1807 | 1.1721 |
| 15 | 1.184 | 1.1786 | 1.1662 | 1.195 | 1.1627 |
| | 9.8% | | | | |
| Rs (Ω/sq) | 15 | 125 | 235 | 345 | 455 |
| 355 | 13.55 | 12.63 | 13.75 | 13.78 | 13.54 |
| 270 | 12.496 | 12.8 | 14.28 | 13.61 | 12.82 |
| 185 | 12.79 | 13.55 | 15.21 | 15.07 | 13.64 |
| 100 | 12.95 | 13.96 | 14.99 | 14.59 | 13.42 |
| 15 | 13.18 | 13.2 | 15.22 | 13.47 | 13.62 |

As shown above, the uniformity of the thickness of the deposited film improves from 8.2% to 3.7%, which shows a reduction in the difference between the minimum value and the maximum value, and a greater similarity in the thickness according to each coordinate. Further, the uniformity of the resistance of the deposited film according to each coordinate has improved from 20.7% to 9.8%. In particular, it is shown that the uniformity of the deposited film improves as the thickness of the deposited film becomes more uniform throughout the entire substrate S.

Hence, the chemical vapor deposition device 100 may improve the deposition uniformity of the substrate S by preventing the purge gas from moving to the upper surface of the substrate S or being stored in the border area of the substrate S by exhausting the purge gas to the outside of the jacket 130. Further, the chemical vapor deposition device 100 may promote smooth exhaustion of the purge gas by exhausting the purge gas to the side of the jacket 130. Moreover, the chemical vapor deposition device 100 may promote the smooth discharge of the purge gas by discharging the purge gas to the side of the jacket 130.

The chemical vapor deposition device 100 may include a suction unit 150 that is installed in the chamber 110, sucks the gas inside the chamber 110, and discharges the gas to the outside. In some embodiments, the suction unit 150 may include a suction pipe 152 installed at a bottom surface of the chamber 110 and a vacuum pump 151 installed in the suction pipe 152. Alternatively, the suction unit 150, including the suction pipe 152 and vacuum pump 151, may be installed at a side surface of the chamber 110. In some embodiments, the purge gas is discharged through the exhaust unit 132 as a result of the pressure difference between the space V and the inside of the chamber 110 when the suction pipe 152 of the suction unit 150 operates.

In one embodiment, the chemical vapor deposition device 100 exhausts the deposition gas, which has flowed into the border area of the substrate S along the space between the space V and the shadow frame 140, to the side of the jacket 130 along the exhaust unit 132 along with the purge gas. In this embodiment, the purge gas is prevented from moving to the upper surface of the substrate S and from reaching the lower surface of the substrate where the deposition gas contacts the support member 120.

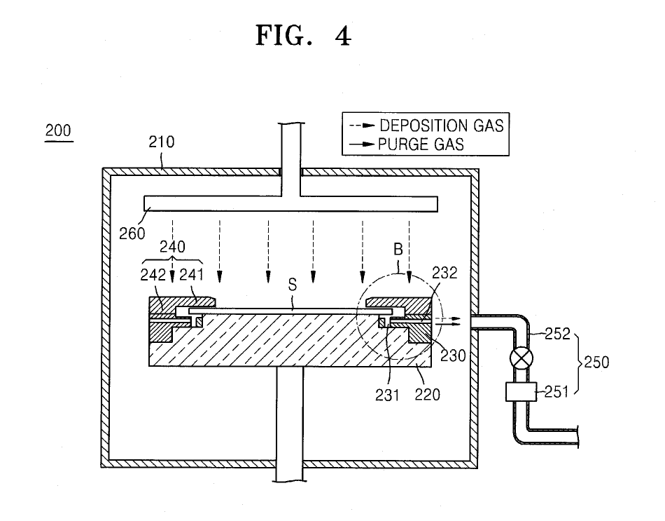

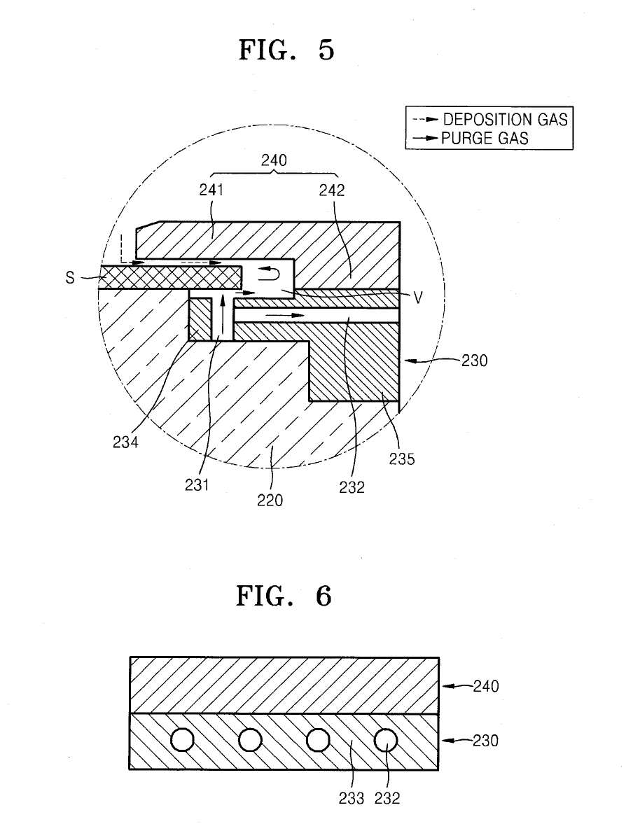

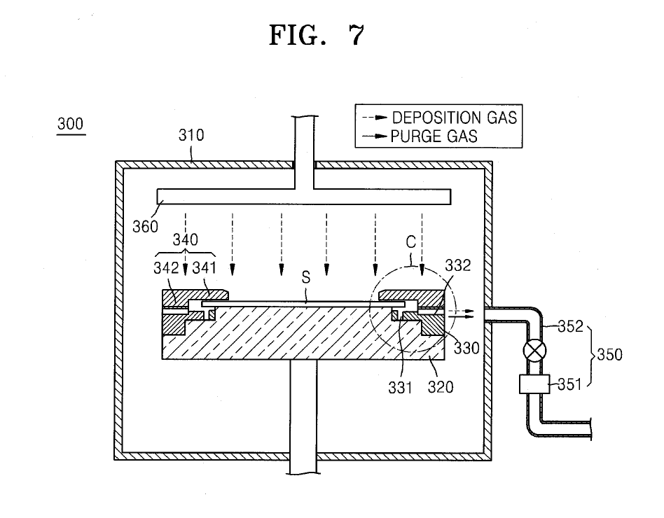

FIG. 4 is an elevation view of a chemical vapor deposition device according to another embodiment of the present invention. FIG. 5 is an enlarged elevation view of portion B of the portion of the chemical vapor deposition device of FIG. 4. FIG. 6 is a side elevation view illustrating a side surface of a jacket and a shadow frame of the portion of the chemical vapor deposition device illustrated in FIG. 5.

Referring to FIGS. 4 and 5, the chemical vapor deposition device 200 may include a support member 220, a jacket 230, a shadow frame 240, and a chamber 210. The support member 220, the jacket 230, the shadow frame 240, and the chamber 210 are similar to the support member 120, the jacket 130, the shadow frame 140, and the chamber 110 illustrated with reference to FIGS. 1 to 3, and thus the detailed description thereof will be omitted here.

Further, the chemical vapor deposition device 200 may include a suction unit 250 that is installed in the chamber 210, sucks the gas inside the chamber 210, and discharges the gas to the outside. In one embodiment, the suction unit 250 includes a suction pipe 252 installed at the side surface of the chamber 210 and a vacuum pump 251 installed in the suction pipe 252.

The jacket 230 may include the exhaust unit 232, the support unit 233, the purge gas supply unit 234, and the jacket body unit or jacket body 235, as illustrated above. In some embodiments, the exhaust unit 232 discharges a part of the purge gas, which is supplied from the purge gas supply opening 231 to the substrate S, to the suction unit 250 at the side surface of the chamber 210. In particular, as described above, the exhaust unit 232 may be formed at the external side of the jacket body unit or jacket body 235, or may be formed as a hole penetrating through the jacket 230. However, if the exhaust unit 232 is formed at the external side of the jacket body unit or jacket body 235, the exhaust unit 232 and the support unit 233 will be similar to those described with reference to FIGS. 1 to 3 above, and thus, the detailed description thereof will be omitted herein. Furthermore, for the convenience of explanation, the exhaust unit 232 will be described in detail centering on the embodiment in which the exhaust unit 232 is formed as a hole penetrating through the jacket 230.

The support unit 233 may be adjacent to the exhaust unit 232. In some embodiments, the support unit 233 is formed inside the jacket 230 that supports the shadow frame 240 by contacting the shadow frame 240.

Furthermore, the exhaust unit 232 may be formed inside the purge gas supply unit 234 and the jacket body unit or jacket body 235 so as to be connected to the purge gas supply opening 231. The exhaust unit 232 may be formed between the support unit 233. Specifically, there may be a plurality of the exhaust units 232, and may be formed at regular intervals. In some embodiments, the support unit 233 is formed between the exhaust units 232 so that the shape of the exhaust unit 232 is not deformed from the load or external force of the shadow frame 240.

Furthermore, the ratio of the width of the support unit 233 to the diameter of the exhaust unit 232 is between about 1:4 and about 4:1. In this embodiment, the diameter of the exhaust unit 232 is between about 20% and about 75% of the thickness of the jacket 230 as described above.

The operation of the chemical vapor deposition device 200 may be performed in a manner that is similar to that in the above description. Specifically, after the substrate S is placed on the support member 220, the support member 220 may be ascended, or the shadow frame 240 may be descended, thereby fixing the substrate S at the support member 220.

When the process is completed, the deposition gas may be supplied to the upper surface of the substrate S through the shower head 260. In this embodiment, the purge gas is sprayed to or toward the lower surface of the substrate S through the purge gas supply opening 231 as described above.

Likewise, if the deposition gas and the purge gas are supplied, the deposition gas may spread on the upper surface of the substrate S, and may be deposited on or toward the substrate S. The deposition gas may flow into the border area of the substrate S as described above. In these embodiments, the purge gas may prevent the lower surface of the substrate S from having deposition gas deposited at the lower surface by blocking the deposition gas.

Furthermore, if the purge gas flows as described above, a problem may occur in the deposition uniformity of the border area of the substrate S, as described above, resulting from the flow of the purge gas. In some embodiments, the portion of the purge gas that caused problems in the deposition uniformity may be discharged to the outside of the jacket 230 through the exhaust unit 232. In particular, the purge gas may move to the suction unit 250 and to the outside through the exhaust unit 232.

In one embodiment, where the air inside the chamber 210 flows through the suction pipe 252 according to the operation of the vacuum pump 251, the purge gas flows through the exhaust unit 232. In particular, as described above, the exhaust unit 232 may be formed at the suction pipe 252 side from the border of the substrate S so that the purge gas may flow to the outside of the jacket 230 through the inside of the exhaust unit 232 according to the operation of the vacuum pump 251. In some embodiments, as described above, if the purge gas flows, the purge gas is prevented from excessively flowing to the border area of the substrate S.

The chemical vapor deposition device 200 may improve the deposition uniformity of the substrate S by preventing the purge gas from moving to the upper surface of the substrate S or being stored in the border area of the substrate S. Further, the chemical vapor deposition device 200 may promote a smooth discharge of the purge gas by discharging the purge gas to the side surface of the jacket 230.

In particular, according to one embodiment, the chemical vapor deposition device 200 exhausts a portion of the purge gas to the side of the jacket 230 before the purge gas is mixed with the deposition gas, so as to prevent an excessive pressure from being formed on the border area of the substrate S due to the purge gas and the deposition gas. Further, if the pressure of the inside of the purge gas supply opening 231 is increased due to the purge gas, the purge gas may be exhausted to the outside through the exhaust unit 232, resulting in a reduction of temporary vibration due to the high pressure or stoppage of the supply of the purge gas.

Furthermore, the chemical vapor deposition device 200 may exhaust the deposition gas and purge gas remaining in the border area of the substrate S to the outside through the exhaust unit 232 after the deposition process is completed, such that the purge gas may flow into a space between the substrate S and the shadow frame 240, or the deposition gas may flow into a space between the substrate S and the support member 220, so as to prevent damage to the deposition uniformity on the surface of the substrate S.

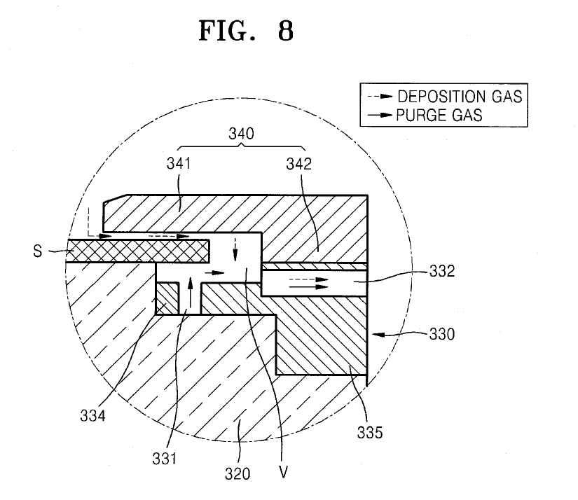

FIG. 7 is an elevation view of a chemical vapor deposition device according to another embodiment of the present invention. FIG. 8 is an enlarged elevation view of portion C of the portion of the chemical vapor deposition device of FIG. 7.

Referring to FIGS. 7 and 8, the chemical vapor deposition device 300 may include the support member 320, the jacket 330, the shadow frame 340 and the chamber 310. The support member 320, the jacket 330, the shadow frame 340, and the chamber 310 are similar to the support member 120, the jacket 130, the shadow frame 140, and the chamber 110 illustrated with reference to FIGS. 1 to 3, and thus the detailed description thereof will be omitted herein.

Further, the chemical vapor deposition device 300 may include a suction unit 350 that is installed in the chamber 310, sucks the gas inside the chamber 310, and discharges the gas to the outside. In some embodiments, the suction unit 350 includes a suction pipe 352 installed at the side surface of the chamber 310 and a vacuum pump 351 installed in the suction pipe 352. Here, the suction unit 350 is similar to the suction units 150, 250 described with reference to FIGS. 1 to 6, and thus the detailed description thereof is omitted herein.

The jacket 330 may include the exhaust unit 332, the support unit, the purge gas supply unit 334, and the jacket body unit or jacket body 335, as illustrated above. In some embodiments, the exhaust unit 332 discharges a part of the deposition gas and the purge gas stored in a space V formed by the border of the substrate S and the lower surface of the shadow frame 340, to the outside through the suction unit 350. In particular, as described above, the exhaust unit 332 may be formed on the surface of the jacket body unit or jacket body 335 or may be formed as a hole penetrating through the jacket body unit or jacket body 335. However, if the exhaust unit 332 is formed at the external side of the jacket body unit or jacket body 335, the exhaust unit 332 and the support unit will be similar to those described with reference to FIGS. 1 to 3, and thus the detailed description thereof will be omitted herein. Furthermore, for the convenience of explanation, the exhaust unit 332, according to one embodiment, will be described in detail centering on the case in which the exhaust unit 332 is formed as a hole penetrating through the jacket 330.

The support unit may be formed to be adjacent to the exhaust unit 332. In some embodiments, the support unit is formed inside the jacket 330 that supports the shadow frame 340 by contacting the shadow frame 340. Furthermore, the exhaust unit 332 may be formed to be connected to a space V formed by the upper surface of the purge gas supply unit 334, the border of the substrate S, and the lower surface of the shadow frame 340. In particular, the exhaust unit 332 may be formed to be connected to at least one of the surface of the purge gas supply unit 334 and the surface of the jacket body unit or jacket body 335 inside the space V formed by the upper surface of the purge gas supply unit 334, the border of the substrate S, and the lower surface of the shadow frame 340.

In some embodiments, the shape of the exhaust unit 332 is a hole having an entrance on the surface of the purge gas supply unit 334 and an exit at the external side of the jacket body unit or jacket body 335. In other embodiments, the shape of the exhaust unit 332 is a hole having an entrance on the side of the jacket body unit or jacket body 335 and an exit at the external side of the jacket body unit or jacket body 335. In particular, the hole-shaped exhaust unit 332 may be a straight line in a longitudinal direction of the jacket body unit or jacket body 335 allowing the deposition gas and the purge gas at the space V, formed by the lower surface of the border and the shadow frame 340, to be guided to the side of the jacket 330.

Furthermore, there may be a plurality of exhaust units 332 that may be formed at regular intervals. In these embodiments, the support unit is formed between the exhaust units 332 such that the shape of the exhaust unit 332 is not deformed from the load or external force of the shadow frame 340.

Furthermore, the ratio of the width of the support unit to the diameter of the exhaust unit 332 may be between about 1:4 and about 4:1. In one embodiment, the diameter of the exhaust unit 332 is between about 20% and about 75% the thickness of the jacket 330 as described above.

Furthermore, the operation of the chemical vapor deposition device 300 may be performed in a manner that is similar to that in the above description. Specifically, after the substrate S is placed on the support member 320, the support member 320 may be ascended, or the shadow frame 340 may be descended, thereby fixing the substrate S at the support member 320.

When the process is completed, the deposition gas may be supplied to the upper surface of the substrate S through the shower head 360. In one embodiment, the purge gas is sprayed to the lower surface of the substrate S through the purge gas supply opening 331 as described above.

Likewise, if the deposition gas and the purge gas are supplied, the deposition gas may spread on the upper surface of the substrate S, and may be deposited on or toward the substrate S. The deposition gas may flow into the border area of the substrate S as described above. In these embodiments, the purge gas prevents the lower surface of the substrate S from being deposited by blocking the deposition gas.

Furthermore, if the purge gas flows as described above, a problem may occur in the deposition uniformity of the border area of the substrate S, as described above, resulting from the flow of the purge gas. In some embodiments, the portion of the purge gas that caused problems in the depositions uniformity and the deposition gas in the space V, formed by the upper surface of the purge gas supply unit 334, the border of the substrate S, and the shadow frame 340, is discharged to the outside of the jacket 330 through the exhaust unit 332. In particular, the purge gas may move to the suction unit 350 and to the outside through the exhaust unit 332.

In one embodiment where the air inside the chamber 310 flows through the suction pipe 352 according to the operation of the vacuum pump 351, the purge gas flows through the exhaust unit 332. In particular, as described above, the exhaust unit 332 may be formed at the space V formed by the upper surface of the purge gas supply unit 334, the border of the substrate S, and the shadow frame 340, to the suction pipe 352, so that the purge gas may flow to the outside of the jacket 330 through the inside of the exhaust unit 332 according to the operation of the vacuum pump 351. In some embodiments, as described above, if the purge gas flows, the purge gas is prevented from excessively flowing to the border area of the substrate S.

Hence, the chemical vapor deposition device 300 may improve the deposition uniformity of the substrate S by preventing the purge gas from moving to the upper surface of the substrate S, or being stored in the border area of the substrate S. Further, the chemical vapor deposition device 300 may promote a smooth discharge of the purge gas by discharging the purge gas to the side surface of the jacket 330.

Furthermore, in one embodiment, the chemical vapor deposition device 300 exhausts the purge gas remaining on the border area of the substrate S to the outside through the exhaust unit 332 after the deposition process is completed, and thereby the purge gas flows into a space V between the substrate S and the shadow frame 340 so as to prevent the damage to the deposition uniformity on the surface of the substrate S.

Though the present invention has been described with reference to the above mentioned embodiments, the present invention may be modified in various ways within the scope of the invention. Therefore, the attached claims may include such modifications within the scope of the present invention.

### DESCRIPTION OF REFERENCE NUMERALS

100, 200, 300: Chemical vapor deposition device
110, 210, 310: Chamber
120, 220, 320: Support member
130, 230, 330: Jacket
131, 231, 331: Purge gas supply opening
132, 232, 332: Exhaust unit
133, 233: Support unit
134, 234, 334: Purge gas supply unit
135, 235, 335: Jacket body unit or jacket body
140, 240, 340: Shadow frame
141, 241, 341: Fixing unit
142, 242, 342: Contact unit
150, 250, 350: Suction unit
151, 251, 351: Vacuum pump
152, 252, 352: Suction pipe
160, 260, 360: Shower head

What is claimed is:

1. A chemical vapor deposition device comprising:
a support member configured to support a lower surface of a substrate;
a shadow frame configured to cover an edge portion of an upper surface of the substrate; and
a jacket having a purge gas supply opening configured to supply a purge gas such that the purge gas exits the purge gas supply opening from a location below the lower surface of the substrate, the jacket being adjacent to a portion of the shadow frame and configured to cover a portion of the lower surface of the substrate,
wherein an exhaust unit is located at the jacket or is between the jacket and the shadow frame.

2. The chemical vapor deposition device of claim 1, wherein the exhaust unit is configured to discharge at least a portion of the purge gas in a direction parallel to the lower surface of the substrate.

3. The chemical vapor deposition device of claim 1, further comprising a chamber housing the support member, the shadow frame, and the jacket.

4. The chemical vapor deposition device of claim 1, wherein the purge gas supply opening extends through the jacket.

5. The chemical vapor deposition device of claim 1, wherein the jacket comprises:
a purge gas supply unit coupled with the purge gas supply opening; and
a jacket body coupled to the purge gas supply unit.

6. The chemical vapor deposition device of claim 5, wherein the purge gas supply unit has a first thickness and the jacket body has a second thickness that is different from the first thickness.

7. The chemical vapor deposition device of claim 6, wherein the first thickness is less than the second thickness.

8. The chemical vapor deposition device of claim 6, wherein a space is between the shadow frame and the purge gas supply unit, and is coupled to the exhaust unit.

9. The chemical vapor deposition device of claim 1, wherein the purge gas supply opening is configured to supply a purge gas to the lower surface of the substrate, and the exhaust unit is configured to discharge at least a portion of the purge gas supplied from the purge gas supply opening to an outside of the jacket.

10. The chemical vapor deposition device of claim 9, wherein the exhaust unit is configured to prevent the purge gas from being supplied toward the upper surface of the substrate by discharging an excess portion of the purge gas to the outside of the jacket.

11. The chemical vapor deposition device of claim 9, further comprising a shower head configured to spray a deposition gas toward the upper surface of the substrate.

12. The chemical vapor deposition device of claim 11, wherein the exhaust unit is configured to discharge a portion of the purge gas supplied from the purge gas supply opening and a portion of the deposition gas supplied from the shower head to the outside of the jacket.

13. The chemical vapor deposition device of claim 1, wherein the exhaust unit is between the shadow frame and the jacket.

14. The chemical vapor deposition device of claim 13, wherein the shadow frame further comprises a fixing unit and a contact unit, wherein the fixing unit is adjacent to and is in contact with the edge portion of the upper surface of the substrate, and the contact unit is adjacent to the exhaust unit, and wherein the shadow frame is configured to fix the substrate between the shadow frame and the support member.

15. The chemical vapor deposition device of claim 1, wherein the exhaust unit comprises a plurality of exhaust units, and the jacket further comprises a support unit between two neighboring ones of the plurality of exhaust units, and wherein a portion of the jacket is in contact with a portion of the shadow frame at each support unit.

16. The chemical vapor deposition device of claim 15, wherein the exhaust unit has a depth that is about 20% to about 75% of a thickness of the jacket.

17. The chemical vapor deposition device of claim 15, wherein the exhaust unit has a diameter that is about 20% to about 75% of a thickness of the jacket.

18. The chemical vapor deposition device of claim 15, wherein a first width of the exhaust unit in a first direction parallel to the substrate is different from a second width of the support unit in the first direction.

19. The chemical vapor deposition device of claim 18, wherein a ratio of the first width to the second width is between 0.25 and 4.

20. The chemical vapor deposition device of claim 15, wherein a diameter of the exhaust unit in a first direction parallel to the substrate is different from a shortest distance between two neighboring ones of the plurality of exhaust units in the first direction, and wherein a ratio of the diameter of the exhaust unit to the shortest distance between two neighboring ones of the plurality of exhaust units is between 0.25 and 4.

21. A chemical vapor deposition device comprising:
a chamber housing
a support member configured to support a lower surface of a substrate;
a shadow frame configured to cover an edge portion of an upper surface of the substrate; and
a jacket having a purge gas supply opening configured to supply a purge gas such that the purge gas exits the purge gas supply opening from a location below the lower surface of the substrate, the jacket being adjacent to a portion of the shadow frame and configured to cover a portion of the lower surface of the substrate,
wherein an exhaust unit is located at the jacket or is between the jacket and the shadow frame; and
a suction unit coupled to the chamber and configured to suction a gas from the chamber.

22. The chemical vapor deposition device of claim 21, wherein the suction unit comprises:
a suction pipe coupled to the chamber; and
a vacuum pump coupled to the suction pipe.

23. The chemical vapor deposition device of claim 21, wherein a portion of the purge gas is discharged through the exhaust unit to an outside of the chamber through the suction unit.

24. The chemical vapor deposition device of claim 21, wherein a portion of the purge gas and a portion of the deposition gas are discharged through the exhaust unit to an outside of the chamber through the suction unit.
